(19) United States
(12) Patent Application Publication
(10) Pub. No.: US 2025/0324568 A1
(43) Pub. Date: Oct. 16, 2025

(54) MANAGING STORAGE NODE CONTACT STRUCTURES IN SEMICONDUCTOR DEVICES

(71) Applicant: Yangtze Memory Technologies Co., Ltd., Wuhan (CN)

(72) Inventors: Sen YAO, Wuhan (CN); Cheng ZHANG, Wuhan (CN); Meng WANG, Wuhan (CN)

(21) Appl. No.: 18/751,154

(22) Filed: Jun. 21, 2024

(30) Foreign Application Priority Data
Apr. 10, 2024 (CN) 202410431311.7

(51) Int. Cl. H10B 12/00; H01L 29/423

(52) U.S. Cl. CPC H10B 12/315; H10B 12/03; H10B 12/50; H10D 30/6735

(57) ABSTRACT

The present disclosure relates to storage node contact structures in semiconductor devices and fabrication methods thereof. An example semiconductor device includes an array of memory cells. The array of memory cells includes a first row of memory cells arranged along a first direction. At least one memory cell of the first row of memory cells includes a first vertical transistor, a first storage node contact structure, and a first storage structure that are stacked along a second direction perpendicular to the first direction. The first storage node contact structure includes a first top portion in contact with the first storage structure and a first bottom portion in contact with the first vertical transistor. A first top cross section of the first top portion is asymmetric.

### CROSS-REFERENCE TO RELATED APPLICATIONS

This application claims priority to Chinese Patent Application No. 202410431311.7, filed on Apr. 10, 2024, which is hereby incorporated by reference in its entirety.

### TECHNICAL FIELD

The present disclosure relates to storage node contact structures in semiconductor devices and fabrication methods thereof.

### BACKGROUND

Semiconductor industry is driven by the need to produce smaller and faster chips. Makers of memory devices and systems also are pushing to improve scaling techniques. Dynamic random-access memory (DRAM) is a common type of memory device widely used in computer systems. Therefore, advanced techniques for mitigating problems and improving scaling of DRAM devices are desirable.

### SUMMARY

The present disclosure describes methods, devices, systems, and techniques for managing storage node contact structures in semiconductor devices, e.g., 3D memory devices such as DRAM.

One aspect of the present disclosure features a semiconductor device including an array of memory cells. The array of memory cells includes a first row of memory cells arranged along a first direction. At least one memory cell of the first row of memory cells includes a first vertical transistor, a first storage node contact structure, and a first storage structure that are stacked along a second direction perpendicular to the first direction. The first storage node contact structure includes a first top portion in contact with the first storage structure and a first bottom portion in contact with the first vertical transistor. A first top cross section of the first top portion is asymmetric.

In some implementations, the first top cross section of the first top portion is asymmetric with respect to a first center cross section of the first storage node contact structure. The first center cross section is perpendicular to the first direction and extends from a center of a first bottom cross section of the first bottom portion to the first top cross section. The first top cross section includes a first part extending from the first center cross section along the first direction and a second part extending from the first center cross section along a fourth direction opposite to the first direction. Along the first direction, a size of the first part of the first top cross section is greater than a size of the second part of the first top cross section.

In some implementations, the array of memory cells further includes a second row of memory cells adjacent to the first row of memory cells. At least one memory cell of the second row of memory cells includes a second vertical transistor, a second storage node contact structure, and a second storage structure that are stacked along the second direction. The second storage node contact structure includes a second top portion in contact with the second storage structure and a second bottom portion in contact with the second vertical transistor. A second top cross section of the second top portion is asymmetric with respect to a second center cross section of the second storage node contact structure. The second center cross section is perpendicular to the first direction and extends from a center of a second bottom cross section of the second bottom portion to the second top cross section. The second top cross section includes a first part extending from the second center cross section along the first direction and a second part extending from the second center cross section along the fourth direction. Along the first direction, a size of the second part of the second top cross section is greater than a size of the first part of the second top cross section.

In some implementations, the first vertical transistor is coupled to the first storage structure through the first storage node contact structure.

In some implementations, the first storage node contact structure includes at least one of a metal, a silicide, or a doped silicon.

In some implementations, the first vertical transistor comprises one of a single-gate structure, a two-gates structure, a three-gates structure, or a gate all around (GAA) structure.

In some implementations, the array of memory cells is coupled to a peripheral circuit through conductive bonding contacts comprised in a bonding layer, and the bonding layer further includes a dielectric material electrically isolating the conductive bonding contacts.

Another aspect of the present disclosure features a semiconductor device. The semiconductor device includes an array of memory cells including a first row of memory cells arranged along a first direction. At least one memory cell of the first row of memory cells includes a first vertical transistor, a first storage node contact structure, and a first storage structure that are stacked along a second direction perpendicular to the first direction. The first storage node contact structure includes a top portion in contact with the first storage structure and a bottom portion in contact with the first vertical transistor. A tangent plane of a side surface of the top portion of the first storage node contact structure on a first side has a smaller slope than a tangent plane of a side surface of the bottom portion on the first side with respect to the first direction.

In some implementations, the tangent plane of the side surface of the top portion of the first storage node contact structure on the first side has a smaller slope than a tangent plane of a side surface of the top portion on a second side with respect to the first direction. The first side and the second side are opposite to each other with respect to a third direction perpendicular to the first direction and the second direction.

In some implementations, a dimension of a cross section of the top portion of the first storage node contact structure is greater than a dimension of a cross section of the bottom portion of the first storage node contact structure.

In some implementations, an angle between the side surface of the top portion of the first storage node contact structure on the first side and the first direction varies from 20 degrees to 70 degrees.

In some implementations, the array of memory cells further includes a second row of memory cells adjacent to the first row of memory cells. At least one memory cell of the second row of memory cells includes a second vertical transistor, a second storage node contact structure, and a second storage structure that are stacked along the second direction. The second storage node contact structure includes a top portion in contact with the second storage structure and a bottom portion in contact with the second vertical transistor. A tangent plane of a side surface of the top portion of the second storage node contact structure on the second side has a smaller slope than a tangent plane of a side surface of the bottom portion of the second storage node contact structure on the second side with respect to the first direction.

In some implementations, the first vertical transistor is coupled to the first storage structure through the first storage node contact structure.

In some implementations, the first storage node contact structure comprises at least one of a metal, a silicide, or a doped silicon.

A further aspect of the present disclosure features a method including forming an array of vertical transistors and a dielectric layer over the array of vertical transistors. The method further includes forming an array of storage node contact holes in the dielectric layer. The array of storage node contact holes includes a first row of storage node contact holes arranged along a first direction. Each storage node contact hole of the array of storage node contact holes extends along a second direction perpendicular to the first direction and has a top portion and a bottom portion along the second direction. The bottom portion is disposed on top of a respective vertical transistor in the array of vertical transistors. The method further includes, for each storage node contact hole of the first row of storage node contact holes, forming a first interior side surface on a first side of the top portion of the storage node contact hole. A tangent plane of the first interior side surface has a smaller slope than a tangent plane of a second interior side surface on the first side of the bottom portion of the storage node contact hole with respect to the first direction.

In some implementations, forming the array of storage node contact holes includes forming the array of storage node contact holes by a same reactive ion etching (RIE) process using a zero angle of incidence with respect to the second direction.

In some implementations, forming the first interior side surface of each of the first row of storage node contact holes includes forming the first interior side surface of each of the first row of storage node contact holes by a first directional ion beam etching (IBE) process using a first angle of incidence perpendicular to the first interior side surface.

In some implementations, the array of storage node contact holes further includes a second row of storage node contact holes adjacent to the first row of storage node contact holes. The method further includes, for each storage node contact hole of the second row of storage node contact holes, forming a third interior side surface on the first side of a top portion of the storage node contact hole. A tangent plane of the third interior side surface has a smaller slope than a tangent plane of a fourth interior side surface on the first side of a bottom portion of the storage node contact hole with respect to the first direction. The tangent plane of the third interior side surface and the tangent plane of the first interior side surface have a same slope with respect to the first direction. The third interior side surface of each of the second row of storage node contact holes is formed during the first directional IBE process.

In some implementations, the array of storage node contact holes further includes a second row of storage node contact holes adjacent to the first row of storage node contact holes. The method further includes for each storage node contact hole of the second row of storage node contact holes, forming a third interior side surface on a second side of a top portion of the storage node contact hole. A tangent plane of the third interior side surface has a smaller slope than a tangent plane of a fourth interior side surface on the second side of a bottom portion of the storage node contact hole with respect to the first direction. The second side is opposite to the first side.

In some implementations, the third interior side surface of each of the second row of storage node contact holes is formed during a second directional IBE process using a second angle of incidence perpendicular to the third interior side surface. Openings of the second row of storage node contact holes are covered during the first directional IBE process. Openings of the first row of storage node contact holes are covered during the second directional IBE process.

Implementations of the present disclosure can provide one or more of the following technical advantages and/or benefits. For example, the techniques provided in the present disclosure enable forming source node contact (SNC) structures with top portions that have asymmetric structures during the manufacture of a memory device. The top portions can serve as landing pads for storage structures to be formed on top of the SNC structures. The landing pads can accommodate a lateral offset between a position of the storage structure and a position of the SNC structure, and thus can provide a reliable connection between the storage structures and the SNC structures and allow the storage structures to have a larger critical dimension (CD). Furthermore, the techniques can avoid building separate storage node landing pads (SNLPs) using complicated techniques, thereby improving the reliability and performance of the memory device and reducing manufacturing efforts and costs. For example, the techniques can address issues caused by an increase density of memory cells in a chip and a Row hammer effect to reduce or eliminate disturbance errors for the memory device.

The techniques implemented herein can be applied to different types of DRAM architectures, e.g., 8F² cell designs, 6F² cell designs, or 4F² cell designs. The techniques can also enable the scaling of DRAM devices from an 18 nanometer (nm) process, a 15 nm process, to a 10 nm process or even a smaller size process. The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIGS. 1A-1B illustrate top views of example memory cell arrays.

FIG. 2 illustrates a side view of a cross-section of an example three-dimensional (3D) semiconductor device.

FIGS. 3A-3B illustrate an example 3D semiconductor device.

FIG. 4 illustrates a side view of an example storage node contact (SNC) structure.

FIGS. 5A-5F illustrate an example fabrication process for forming an SNC structure array.

FIG. 6 illustrates a flow chart of an example process.

FIG. 7 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

A memory device, such as a dynamic random-access memory (DRAM), can use a storage node landing pad (SNLP) to connect a storage node contact (SNC) structure and a storage node (SN) (also referred to as a storage structure). The SNLP can provide a more reliable connection between the SNC structure and the storage structure (e.g., a capacitor) and enable storage structures in the memory device to have larger critical dimensions (CDs).

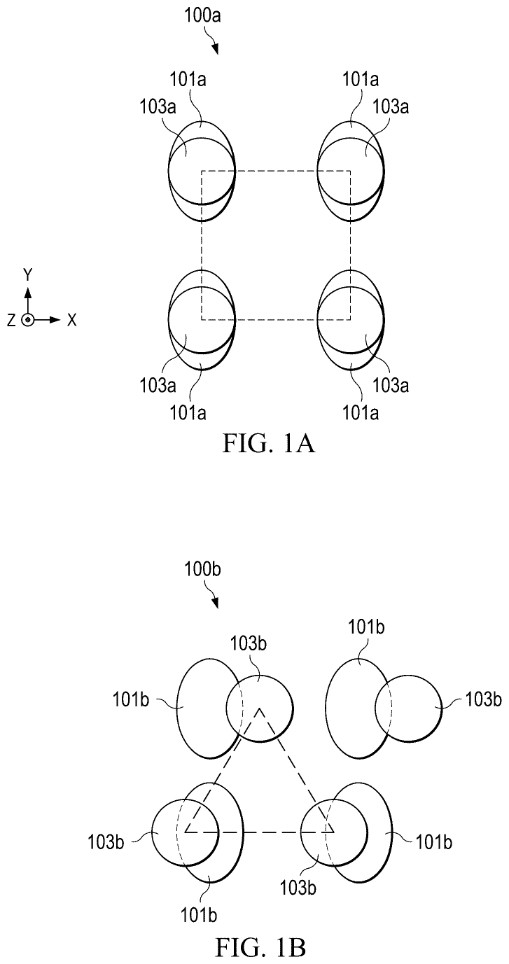

FIGS. 1A-1B illustrate top views of example memory cell arrays 100a and 100b in a semiconductor device such as a memory device. Each of memory cell arrays 100a and 100b can include, for example, DRAM cells. It is noted that X, Y, and Z axes (also referred to as X, Y, and Z directions) are included in FIGS. 1A-1B to further illustrate the spatial relationship of various components in the semiconductor device. A substrate of the semiconductor device includes two lateral surfaces extending laterally in the X-Y plane: a top surface on the front side of a wafer on which a component of the semiconductor device can be formed, and a bottom surface on the backside opposite to the front side of the wafer. The Z direction is perpendicular to both the X and Y directions. As used herein, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

As shown in FIG. 1A, each memory cell in memory cell array 100a includes a SNC structure 101a and a storage structure 103a. The SNC structures 101a and the storage structures 103a are both arranged in a square pattern, which allows each storage structure 103a to be aligned with and coupled to a respective SNC structure 101a along the vertical direction (e.g., the Z direction). FIG. 1B illustrates memory cell array 100b including SNC structures 101b and storage structures 103b. SNC structures 101b are still arranged in a square pattern. Storage structures 103b are arranged in a triangle pattern. The triangle pattern allows storage structures 103b to have larger CDs (compared to storage structures 103a of FIG. 1A), thereby providing more space for the storage structures 103b while maintaining the same density. However, due to the difference between arrangement patterns of SNC structures 101b and storage structures 103b, the alignment between each SNC structure 101b and a corresponding storage structure 103b along the vertical direction may not be perfect. In other words, a position of the SNC structure 101b and a position of the storage structure 103b can have an offset in the X-Y plane. As shown in FIG. 1B, a contact area of a SNC structure 101b and a corresponding storage structure 103b can have a reduced size due to the offset, thereby making connections between SNC structures 101b and storage structures 103b unstable.

Conventional techniques can add SNLPs after forming SNC structures 101b. For example, each SNLP can extend from a SNC structure 101b towards a corresponding storage structure 103b, which is to be connected to the SNLP. As such, better connections between SNC structures 101b and storage structures 103b can be provided. However, forming separate SNC structures and SNLPs may involve complicated techniques (such as self-alignment double pattern (SADP) and self-alignment reverse pattern (SARP)) and extra fabrication processes, which may increase the manufacturing cost and reduce the production yield.

Implementations of the present disclosure provide techniques for forming a SNC structure that has a top portion serving as a landing pad for a storage structure. The top portion of the SNC structure can have an asymmetric structure to have a larger size as the landing pad. The details of one or more implementations of the subject matter of this present disclosure are set forth in the accompanying drawings and the description below. Other features, aspects, and advantages of the subject matter will become apparent from the description, the drawings, and the claims.

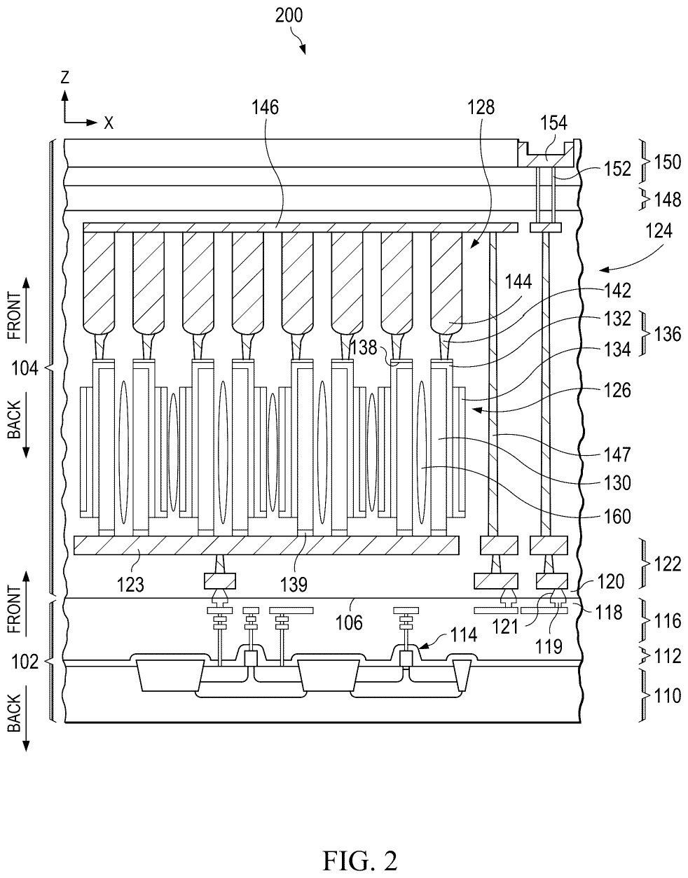

FIG. 2 illustrates a side view of a cross-section of an example 3D semiconductor device 200. In some implementations, the 3D semiconductor device 200 can be a 3D DRAM using a 4F² cell design. In the 4F² cell design, F represents a half-WL (word line) pitch as a minimum feature size, and a 4F² cell indicates that the cell (such as DRAM cell) has an area size of 4F². It is understood that FIG. 2 is for illustrative purposes only and may not necessarily reflect the actual device structure (e.g., interconnections) in practice. In some implementations, the 3D semiconductor device 200 is a bonded chip including a first semiconductor structure 102 and a second semiconductor structure 104 stacked over the first semiconductor structure 102. The first and second semiconductor structures 102 and 104 can be jointed at bonding interface 106 therebetween.

As shown in FIG. 2, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on and/or in the substrate 110. In some implementations, the peripheral circuits 112 include a plurality of transistors 114 (e.g., planar transistors and/or 3D transistors). Trench isolations (e.g., shallow trench isolations (STIs)) and doped regions (e.g., wells, sources, and drains of transistors 114) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die 102.

In some implementations, the first semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and VIA contacts. The interconnect layer 116 can further include one or more interlay dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 2, the first semiconductor structure 102 has a front side and a back side, and the first semiconductor structure 102 can further include a bonding layer 118 at the back side at the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. Similarly, as shown in FIG. 2, the second semiconductor structure 104 can also include a bonding layer 120 at the bonding interface 106 and above the bonding layer 118 of the first semiconductor structure 102. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 2. The dielectric layer can include the bonding interface 106 having the bonding contacts 121.

The second semiconductor structure 104 can be bonded on top of the first semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 of the first semiconductor structure 102 and the bottom surface of the bonding layer 120 of the second semiconductor structure 104.

In some implementations, the second semiconductor structure 104 further includes an interconnect layer 122 including bit lines 123 above the bonding layer 120 to transfer electrical signals. The interconnect layer 122 can include a plurality of interconnects, such as mid end of line (MEOL) interconnects and back end of line (BEOL) interconnects. In some implementations, the interconnects in interconnect layer 122 also include local interconnects, such as the bit lines 123 and word line contacts (not shown). The interconnect layer 122 can further include one or more ILD layers in which the interconnect lines and via contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the bit lines 123 and bit line contacts in the interconnect layer 122 through the bonding contacts 121 and 119 in the bonding layers 120 and 118 and the interconnect layer 116. In some implementations, the bit line 123 is a metal bit line, as opposed to semiconductor bit lines (e.g., doped silicon bit lines). For example, the bit line 123 may include W, Co, Cu, Al, or any other suitable metals having higher conductivities than doped silicon. In some implementations, the bit line contact is an ohmic contact as opposed to a Schottky contact.

In some implementations, e.g., as discussed with further details below, the bit line 123 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

In some implementations, the second semiconductor structure 104 includes a DRAM device in which memory cells are provided in the form of an array of DRAM cells 124 above the interconnect layer 122 and the bonding layer 120. That is, the interconnect layer 122 including the bit lines 123 can be disposed between bonding layer 120 and array of DRAM cells 124. A bit line 123 in the interconnect layer 122 can be coupled to a string of DRAM cells 124. In some implementations, the second semiconductor structure 104 is formed on a semiconductor die and can be referred to as array die 104.

In some implementations, a semiconductor device can include multiple array dies (e.g., the array die 104) and a CMOS die (e.g., the CMOS die 102). The multiple array dies and the CMOS die can be stacked and bonded together. The CMOS die can be respectively coupled to each of the multiple array dies, and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each DRAM cell 124 can include a vertical transistor 126 and a capacitor 128 coupled to the vertical transistor 126. DRAM cell 124 can be a 1T1C cell consisting of one transistor and one capacitor. It is understood that DRAM cell 124 may be of any suitable configurations, such as 2T1C cell, 3T1C cell, etc. The vertical transistor 126 can be a MOSFET used to switch a respective DRAM cell 124. In some implementations, the vertical transistor 126 includes a semiconductor body 130 (the active region in which a channel can form) extending vertically (in the z-direction), and a gate structure 136 in contact with one side of semiconductor body 130. In a single-gate vertical transistor, the semiconductor body 130 can have a cuboid shape or a cylinder shape, and the gate structure 136 can abut a single side of semiconductor body 130 in a plane view, e.g., as shown in FIG. 2. In some implementations, the vertical transistor 126 has a structure including two or more gates, e.g., a two-gates structure, a three-gates structure, or a gate all around (GAA) structure. In some implementations, the gate structure 136 includes a gate electrode 134 and a gate dielectric 132 laterally between the gate electrode 134 and the semiconductor body 130 in a bit line direction (e.g., in the x-direction). In some implementations, the gate dielectric 132 abuts one side of the semiconductor body 130, and the gate electrode 134 abuts the gate dielectric 132.

As shown in FIG. 2, in some implementations, the semiconductor body 130 has two ends (the upper end and lower end in FIG. 2) in the vertical direction (the z-direction), and at least one end (e.g., the lower end) extends beyond gate dielectric 132 in the vertical direction (the z-direction) into the ILD layers. In some implementations, one end (e.g., the upper end) of the semiconductor body 130 is flush with the respective end (e.g., the upper end) of the gate dielectric 132. In some implementations, both ends (the upper end and lower end) of the semiconductor body 130 extend beyond the gate electrode 134, respectively, in the vertical direction (the z-direction) into ILD layers. That is, the semiconductor body 130 can have a larger vertical dimension (e.g., the depth) than that of the gate electrode 134 (e.g., in the z-direction), and neither the upper end nor the lower end of semiconductor body 130 is flush with the respective end of the gate electrode 134. Thus, short circuits between the bit lines 123 and the word lines/gate electrodes 134 or between the word lines/gate electrodes 134 and the capacitors 128 can be avoided. The vertical transistor 126 can further include a source 138 and a drain 139 (which can also be referred to as a drain 138 and a source 139 as their locations may be interchangeable) disposed at the two ends (the upper end and lower end) of the semiconductor body 130, respectively, in the vertical direction (the z-direction). In some implementations, one of the source 138 and the drain 139 (e.g., at the upper end in FIG. 2) is coupled to the capacitor 128, and the other one of the source 138 and the drain 139 (e.g., at the lower end in FIG. 2) is coupled to the bit line 123. That is, the vertical transistor 126 can have a first terminal in the positive z-direction and a second terminal opposite the first terminal in the negative z-direction, as shown in FIG. 2.

In some implementations, the semiconductor body 130 includes semiconductor materials, such as single crystalline silicon, polysilicon, amorphous silicon, Ge, any other semiconductor materials, or any combinations thereof. In one example, semiconductor body 130 may include single crystalline silicon. The source 138 and the drain 139 can be doped with N+ type dopants (e.g., Phosphorus (P) or Arsenic (As)) or P-type dopants (e.g., Boron (B) or Gallium (Ga)) at a desired doping level. In some implementations, a silicide layer, such as a metal silicide layer, is formed between the drain 139 of the vertical transistor 126 and the bit line 123 as the bit line contact or between the source 138 of the vertical transistor 126 and the first electrode of the capacitor 128 as SNC structure (also referred to as capacitor contact) 142 to reduce the contact resistance. In some implementations, gate dielectric 132 includes dielectric materials, such as silicon oxide, silicon nitride, or high-k dielectrics including, but not limited to, Al2O3, HfO2,Ta2O5, ZrO2, TiO2, or any combination thereof. In some implementations, gate electrode 134 includes a conductive material including, but not limited to W, Co, Cu, Al, TiN, TaN, polysilicon, silicide, or any combination thereof. In some implementations, the gate electrode 134 includes multiple conductive layers, such as a W layer over a TiN layer. In one example, the gate structure 136 may be a “gate oxide/gate poly” gate in which the gate dielectric 132 includes silicon oxide and gate electrode 134 includes doped polysilicon. In another example, gate structure 136 may be an HKMG in which gate dielectric 132 includes a high-k dielectric and gate electrode 134 includes a metal.

As described above, since the gate electrode 134 may be part of a word line or extend in the word line direction (e.g., the y-direction) as a word line, the second semiconductor structure 104 of the 3D semiconductor device 200 can also include a plurality of word lines each extending in the word line direction (the y-direction). Each word line 134 can be coupled to a row of DRAM cells 124. That is, the bit line 123 and the word line 134 can extend in two perpendicular lateral directions, and the semiconductor body 130 of the vertical transistor 126 can extend in the vertical direction perpendicular to the two lateral directions in which the bit line 123 and the word line 134 extend. Word lines 134 are in contact with word line contacts (not shown). In some implementations, the word lines 134 include conductive materials including, but not limited to W, Co, Cu, Al, TiN, TaN, polysilicon, silicides, or any combination thereof. In some implementations, the word line 134 includes multiple conductive layers, such as a W layer over a TiN layer, as shown in FIG. 2.

In some implementations, as shown in FIG. 2, the vertical transistor 126 extends vertically through and contacts the word lines 134, and the drain 139 of vertical transistor 126 at the lower end thereof is in contact with the bit line 123 (or bit line contact if any). Accordingly, the word lines 134 and the bit lines 123 can be disposed in different planes in the vertical direction due to the vertical arrangement of vertical transistor 126, which simplifies the routing of the word lines 134 and the bit lines 123. In some implementations, the bit lines 123 are disposed vertically between the bonding layer 120 and the word lines 134, and the word lines 134 are disposed vertically between the bit lines 123 and the capacitors 128. The word lines 134 can be coupled to the peripheral circuits 112 in the first semiconductor structure 102 through word line contacts (not shown) in the interconnect layer 122, the bonding contacts 121 and 119 in the bonding layers 120 and 118, and the interconnects in the interconnect layer 116. Similarly, the bit lines 123 in the interconnect layer 122 can be coupled to the peripheral circuits 112 in the first semiconductor structure 102 through the bonding contacts 121 and 119 in the bonding layers 120 and 118 and the interconnects in the interconnect layer 116.

In some implementations, the vertical transistors 126 can be arranged in a mirror-symmetric manner to increase the density of DRAM cells 124 in the bit line direction (the x-direction). As shown in FIG. 2, two adjacent vertical transistors 126 in the bit line direction are mirror-symmetric to one another with respect to a trench isolation 160. That is, the second semiconductor structure 104 can include a plurality of trench isolations 160 each extending in the word line direction (the y-direction) in parallel with word lines 134 and disposed between semiconductor bodies 130 of two adjacent rows of the vertical transistors 126. In some implementations, the rows of vertical transistors 126 separated by the trench isolation 160 are mirror-symmetric to one another with respect to the trench isolation 160. The trench isolation 160 can be formed with dielectric materials including, but not limited to, silicon oxide, silicon nitride, silicon oxynitride, low-k dielectrics, or any combination thereof. It is understood that the trench isolation 160 may include an air gap each disposed laterally between adjacent semiconductor bodies 130. Air gaps may be formed due to the relatively small pitches of vertical transistors 126 in the bit line direction (e.g., the x-direction). On the other hand, the relatively large dielectric constant of air in air gaps (e.g., about 4 times of the dielectric constant of silicon oxide) can improve the insulation effect between vertical transistors 126 (and rows of DRAM cells 124) compared with some dielectrics (e.g., silicon oxide). Similarly, in some implementations, air gaps are formed laterally between word lines/gate electrodes 134 in the bit line direction as well, depending on the pitches of word lines/gate electrodes 134 in the bit line direction.

As shown in FIG. 2, in some implementations, a capacitor 128 includes a first electrode 144 above and coupled to the source 138 of vertical transistor 126, e.g., the upper end of the semiconductor body 130, via a SNC structure 142. In some implementations, the SNC structure 142 is an ohmic contact, such as a metal silicide contact, as opposed to a Schottky contact. For example, the SNC structure 142 may include metal silicides, such as WSi, CoSi, CuSi, AlSi, or any other suitable metal silicides having higher conductivities than doped silicon. The capacitor 128 can also include a capacitor dielectric above and in contact with the first electrode 144, and a second electrode above and in contact with the capacitor dielectric. That is, the capacitor 128 can be a vertical capacitor in which the electrodes and capacitor dielectric are stacked vertically (in the z-direction), and the capacitor dielectric can be sandwiched between the electrodes. In some implementations, each first electrode is coupled to source 138 of a respective vertical transistor 126 in the same DRAM cell, while all second electrodes are coupled to a common plate 146 coupled to the ground, e.g., a common ground. The capacitor 128 can have a first end in the negative z-direction and a second end opposite the first end in the positive z-direction, as shown in FIG. 2. In some implementations, the first end of the capacitor 128 is coupled to the first terminal of the vertical transistor 126 via an ohmic contact (e.g., the SNC structure 142 made of a metal silicide material). As shown in FIG. 2, the second semiconductor structure 104 can further include a capacitor contact 147 (e.g., a conductor) in contact with a common plate 146 for coupling the capacitors 128 to the peripheral circuits 112 or to the ground directly. In some implementations, the capacitor contact 147 (e.g., a conductor) extends in the z-direction from the dielectric layer of the bonding layer 120 to couple to the second end of the capacitor 128 via the common plate 146, as shown in FIG. 2. In some implementation, the ILD layer in which the capacitors 128 are formed has the same dielectric material as the two ILD layers into which the semiconductor body 130 extends, such as silicon oxide.

It is understood that the structure and configuration of a capacitor 128 are not limited to the example in FIG. 2 and may include any suitable structure and configuration, such as a planar capacitor, a stack capacitor, a multi-fins capacitor, a cylinder capacitor, a trench capacitor, or a substrate-plate capacitor. In some implementations, the capacitor dielectric includes dielectric materials, such as silicon oxide, silicon nitride, or high-k dielectrics including, but not limited to, Al2O3, HfO2, Ta2O5, ZrO2, TiO2, or any combination thereof. It is understood that in some examples, a capacitor 128 may be a ferroelectric capacitor used in a FRAM cell, and the capacitor dielectric may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 2, vertical transistor 126 extends vertically through and contacts the word lines 134, drain 139 of vertical transistor 126 at the lower end thereof is in contact with the bit line 123, and source 138 of vertical transistor 126 at the upper end thereof is coupled to the capacitor 128. That is, the bit line 123 and the capacitor 128 can be disposed in different planes in the vertical direction and coupled to opposite ends of vertical transistor 126 of DRAM cell 124 in the vertical direction due to the vertical arrangement of vertical transistor 126. In some implementations, the bit line 123 and the capacitor 128 are disposed on opposite sides of the vertical transistor 126 in the vertical direction, which simplifies the routing of the bit lines 123 and reduces the coupling capacitance between the bit lines 123 and the capacitors 128 compared with DRAM cells in which the bit lines and capacitors are disposed on the same side of the planar transistors.

As shown in FIG. 2, in some implementations, the vertical transistors 126 are disposed vertically between the capacitors 128 and the bonding interface 106. That is, the vertical transistors 126 can be arranged closer to the peripheral circuits 112 of the first semiconductor structure 102 and the bonding interface 106 than the capacitors 128. Since the bit lines 123 and the capacitors 128 are coupled to opposite ends of the vertical transistors 126, the bit lines 123 (as part of the interconnect layer 122) are disposed vertically between the vertical transistors 126 and the bonding interface 106 As a result, the interconnect layer 122 including bit lines 123 can be arranged close to the bonding interface 106 to reduce the interconnect routing distance and complexity.

In some implementations, second semiconductor structure 104 further includes a substrate 148 disposed above the DRAM cells 124. As described below with respect to the fabrication process, the substrate 148 can be part of a carrier wafer. It is understood that in some examples, the substrate 148 may not be included in the second semiconductor structure 104.

As shown in FIG. 2, the second semiconductor structure 104 can further include a pad-out interconnect layer 150 above the substrate 148 and the DRAM cells 124. The pad-out interconnect layer 150 can include interconnects, e.g., contact pads 154, in one or more ILD layers. The pad-out interconnect layer 150 and the interconnect layer 122 can be formed on opposite sides of the DRAM cells 124. The capacitors 128 can be disposed vertically between the vertical transistors 126 and the pad-out interconnect layer 150. In some implementations, the interconnects in pad-out interconnect layer 150 can transfer electrical signals between the 3D semiconductor device 200 and outside circuits, e.g., for pad-out purposes.

In some implementations, the second semiconductor structure 104 further includes one or more contacts 152 extending through the substrate 148 and part of the pad-out interconnect layer 150 to couple the pad-out interconnect layer 150 to the DRAM cells 124 and the interconnect layer 122. As a result, the peripheral circuits 112 can be coupled to the DRAM cells 124 through the interconnect layers 116 and 122 as well as the bonding layers 120 and 118, and the peripheral circuits 112 and the DRAM cells 124 can be coupled to outside circuits through contacts 152 and pad-out interconnect layer 150. Contact pads 154 and contacts 152 can include conductive materials including, but not limited to, W, Co, Cu, Al, silicides, or any combination thereof. In one example, the contact pad 154 may include Al, and the contact 152 may include W. In some implementations, the contact 152 includes a via surrounded by a dielectric spacer (e.g., having silicon oxide) to electrically separate the via from substrate 148. Depending on the thickness of substrate 148, contact 152 can be an ILV having a depth in the submicron level (e.g., between 10 nm and 1 μm), or a TSV having a depth in the micron-or tens micron-level (e.g., between 1 μm and 100 μm).

Although not shown, it is understood that the pad-out of 3D memory devices is not limited to from the second semiconductor structure 104 having DRAM cells 124 as shown in FIG. 2 and may be from the first semiconductor structure 102 having peripheral circuit 112. Although not shown, it is also understood that the air gaps between word lines 134 and/or between semiconductor bodies 130 may be partially or fully filled with dielectrics. Although not shown, it is further understood that more than one array of DRAM cells 124 may be stacked over one another to vertically scale up the number of DRAM cells 124.

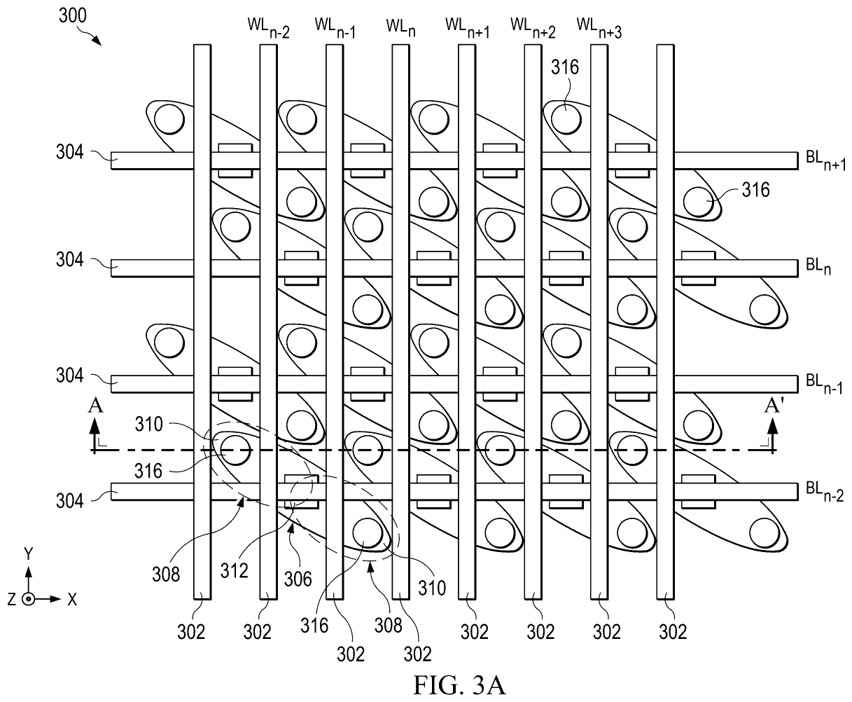

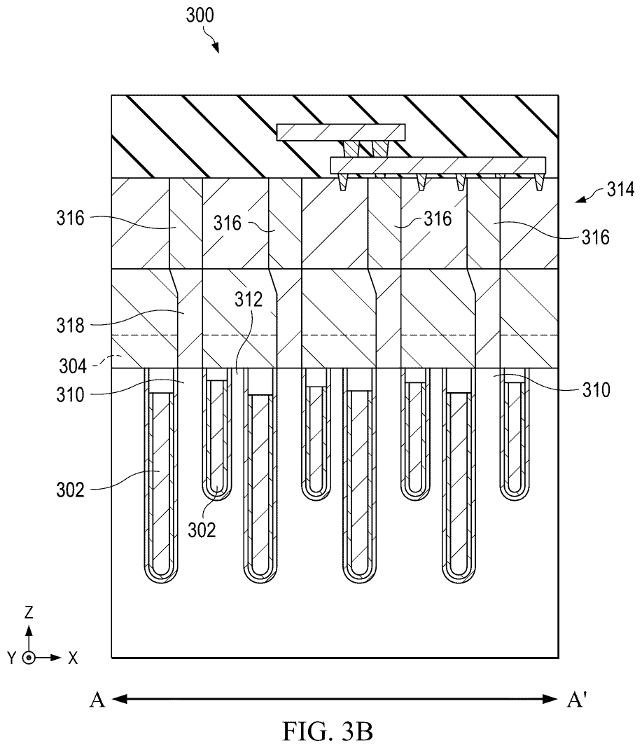

FIG. 3A illustrates a top view of an example 3D semiconductor device 300. In some implementations, the 3D semiconductor device 300 can be a 3D DRAM using a 6F² cell design. In the 6F² cell design, F represents a half-WL (word line) pitch as a minimum feature size, and a 6F² cell indicates that the cell (such as DRAM cell) has an area size of 6F². It is understood that FIG. 3A is for illustrative purposes only and may not necessarily reflect the actual device structure (e.g., interconnections) in practice. The 3D semiconductor device 300 includes word lines 302 (also referred to as buried word lines) extending in the Y direction and bit lines 304 extending in the X direction. The 3D semiconductor device 300 includes active regions 306. The word lines 302 extend through the active regions 306, forming an array of transistors 308. Specifically, each active region 306 is extended through by two parallel word lines 302, thereby forming two transistors sharing one terminal (either a source or a drain) in the same active region. A shown in FIG. 3A, a source 310 and a drain 312 of each transistor are disposed on both sides of the word line 302. In some implementations, 310 can be referred to as a drain and 312 can be referred to as a source as their locations may be interchangeable.

The bit lines 304 can be positioned on top of the active regions 306. The 3D semiconductor device 300 further includes a capacitor array 314 (as shown in FIG. 3B) located above the active regions 306. The capacitor array 314 includes an array of capacitors 316. Within one active region 306, a drain 312 shared by both transistors 308 is connected to the same bit line 304. The transistors 308 have their sources 310 coupled to two respective capacitors 316.

FIG. 3B illustrates a cross-sectional view of the 3D semiconductor device 300 along a cut line AA′ of FIG. 3A. The 3D semiconductor device 300 further include SNC structures 318 located between the active regions 306 and the capacitor array 314 along the Z direction. Each source 310 is coupled to a respective capacitor 316 of the capacitor array 314 through a corresponding SNC structure 318.

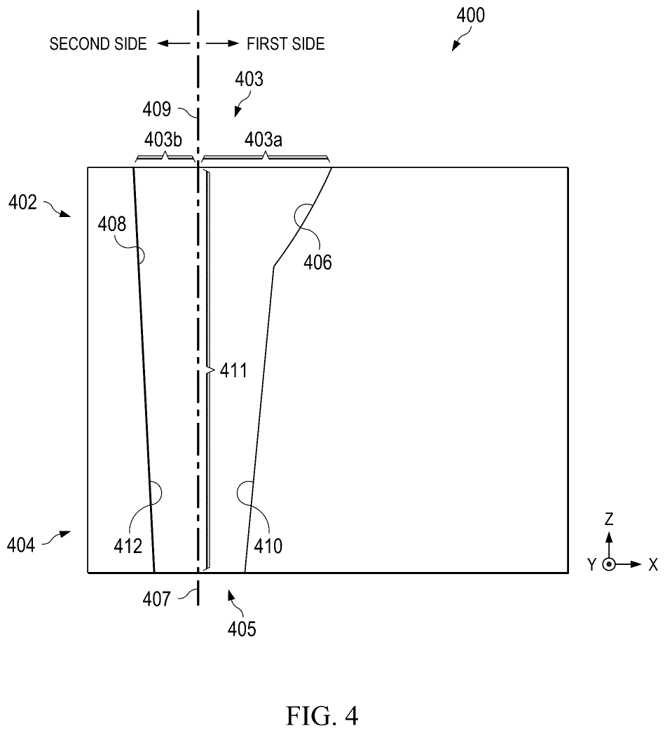

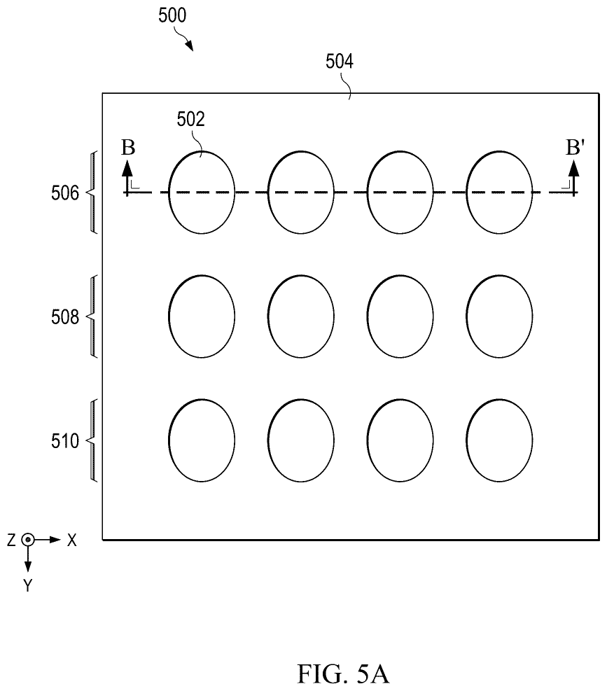

FIG. 4 illustrates a side view of an example SNC structure 400 of a semiconductor device, e.g., the semiconductor device 200 of FIG. 2 or the semiconductor device 300 of FIGS. 3A-3B. In some implementations, the SNC structure 400 can be an example of the SNC structure 142 of FIG. 2 or the SNC structure 318 of FIG. 3B. The SNC structure 400 can be in a DRAM cell (e.g., the cell 124 of FIG. 2) and can connect a transistor (e.g., the vertical transistor 126 of FIG. 2) of the DRAM cell and a storage structure (e.g., the capacitor 128 of FIG. 2) of the DRAM cell. The transistor, the SNC structure 400, and the storage structure can be stacked along a vertical direction (e.g., the Z direction). In some implementations, the SNC structure 400 can include conductive materials including, but not limited to, W, Co, Cu, Al, doped silicon, silicides, or any combination thereof. The SNC structure 400 can include a top portion 402 in contact with the storage structure (not shown in FIG. 4) and a bottom portion 404 in contact with the transistor (not shown in FIG. 4). The top portion 402 can have a top cross section 403 extending in the X-Y plane (e.g., perpendicular to the Z direction). The bottom portion 404 can have a bottom cross section 405 extending in the X-Y plane (e.g., perpendicular to the Z direction). A dimension of the top cross section 403 is greater than a dimension of the bottom cross section 405. An axis 407 is defined as a projection line extending from a center of the bottom cross section 405 to the top cross section 403 along the Z direction. The axis 407 can be in a reference plane 409 that extends along the Y direction and the Z direction. In other words, the reference plane 409 cuts through the center of the bottom cross section 405 and extends in the Y direction and the Z direction. The reference plane 409 can overlap with the axis 407 in FIG. 4 since FIG. 4 provides a side view along the Y direction. A center cross section 411 of the SNC structure 400 can be formed in an intersection of the reference plane 409 and the SNC structure 400. The center cross section 411 can be perpendicular to the X direction and can extend from the center of the bottom cross section 405 to the top cross section 403. In some implementations, the top cross section 403 is asymmetric with respect to the reference plane 409 (and the center cross section 411). The top cross section 403 can be divided into a part 403a and another part 403b by the reference plane 409 (and the center cross section 411). The part 403a extends from the reference plane 409 (and the center cross section 411) along a first direction (e.g., the X direction), and the part 403b extends from the reference plane 409 (and the center cross section 411) along a second direction opposite to the first direction. In some implementations, along the first direction, a size of the part 403a is greater than a size of the part 403b.

The top portion 402 has a side surface 406 on one side of the SNC structure 400 (e.g., the right side, which is also referred to as the first side as shown in FIG. 4) and a side surface 408 on the other side (e.g., the left side, which is also referred to as the second side as shown in FIG. 4). The first side and the second side are opposite to each other with respect to the reference plane 409 (and the center cross section 411). The bottom portion 404 has a side surface 410 on the first side and a side surface 412 on the second side. In some implementations, a tangent plane of the side surface 406 can have a smaller slope than a tangent plane of the side surface 410 with respect to the X direction. In some implementations, the tangent plane of the side surface 406 can have a smaller slope than a tangent plane of the side surface 408 with respect to the X direction. In some implementations, an angle between the axis 407 and the tangent plane of the side surface 406 is in a range between 20 degrees and 70 degrees.

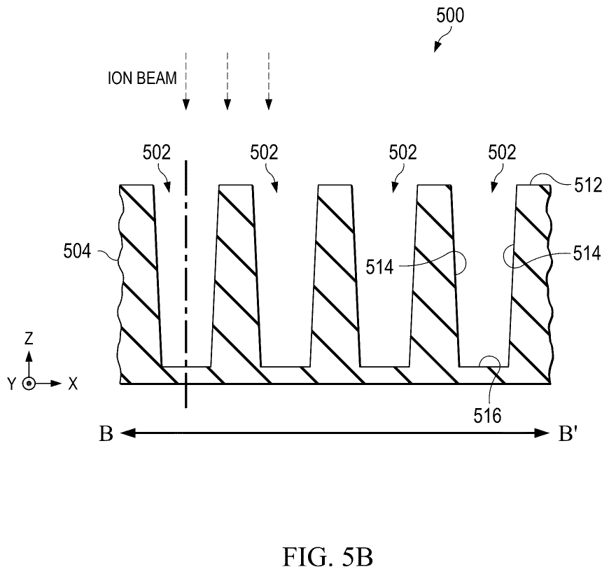

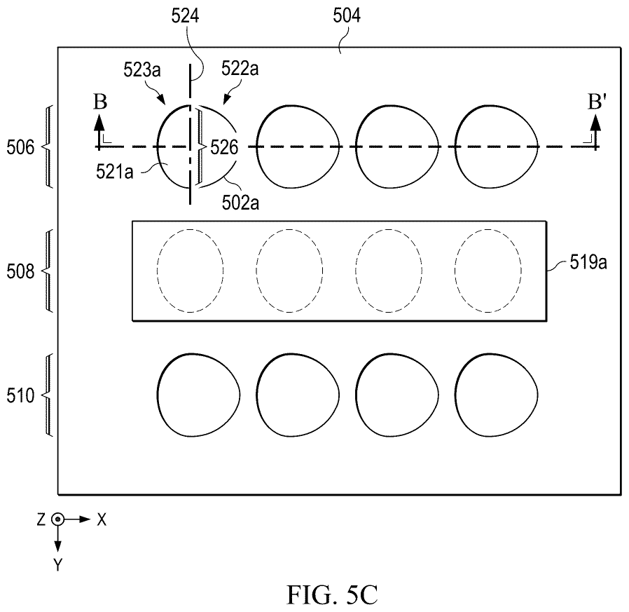

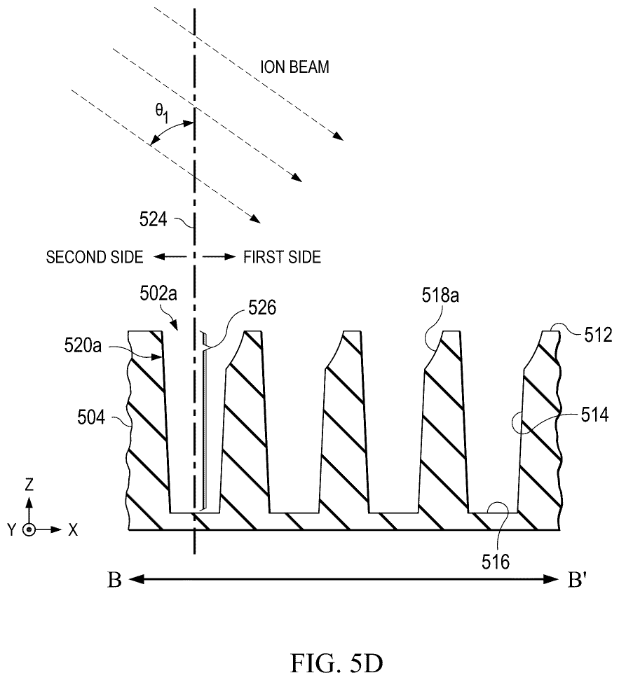

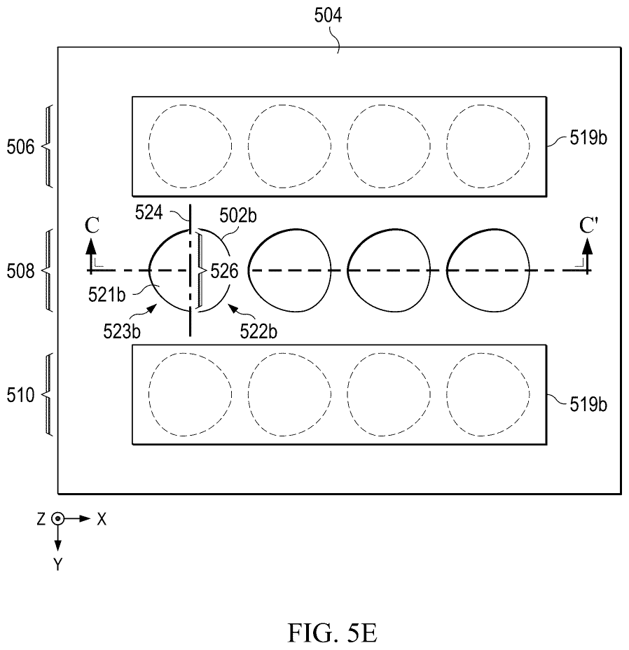

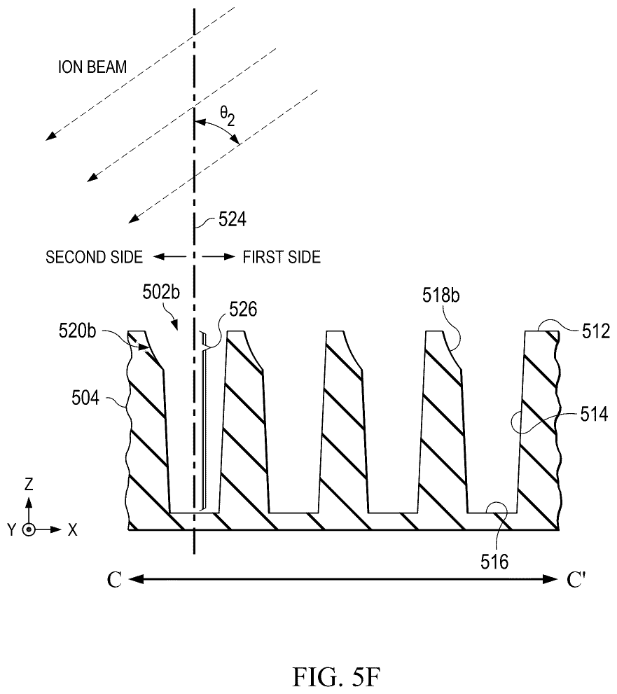

FIGS. 5A-5F illustrate an example fabrication process for forming an SNC structure array of a semiconductor device, e.g., the semiconductor device 200 of FIG. 2 or the semiconductor device 300 of FIGS. 3A-3B. Each SNC structure of the SNC structure array can be an example of the SNC structure 142 of FIG. 2, the SNC structure 318 of FIG. 3B, or the SNC structure 400 of FIG. 4.

FIG. 5A illustrates a top view of an array 500 of SNC holes 502. FIG. 5B illustrates a side view of a cross section of the array 500 along cut line BB′ of FIG. 5A. The array 500 can be formed in a dielectric layer 504. Each SNC hole 502 extends along the vertical direction (e.g., the Z direction). The SNC holes 502 of the array 500 can form rows (e.g., rows 506, 508, and 510) arranged along a first horizontal direction (e.g., the X direction) perpendicular to the vertical direction and can form columns arranged along a second horizontal direction (e.g., the Y direction) perpendicular to both the vertical direction and the first horizontal direction. Row 508 is adjacent to row 506, and row 510 is adjacent to row 508. It is understood that shapes of the openings of the SNC holes 502 are not limited to ellipse shapes or oval shapes as shown in FIG. 5A, and may include any suitable shapes, such as squares, rectangles, or circles. It is also understood that while FIG. 5A illustrates an SNC hole array having only three rows, any suitable number of rows can be included in an SNC hole array.

In some implementations, the dielectric layer 504 can be formed over a transistor array (not shown). For example, the transistor array can include transistors such as the vertical transistor 126 of FIG. 2. Each SNC hole 502 can be formed on top of a corresponding transistor of the transistor array and can extend to a terminal (either a source or a drain) of the corresponding transistor along the Z direction. In some implementations, the SNC holes 502 of the array 500 can be formed by etching the dielectric layer 504. For example, the SNC holes 502 can be formed by a reactive ion etching (RIE) process. The RIE process can etch the dielectric layer 504 by applying an ion beam to the dielectric layer 504 at a zero angle of incidence with respect to the Z direction. In other words, the SNC holes 502 of the array 500 can be formed by directing the ion beam towards the dielectric layer 504 along a direction perpendicular to a top surface 512 of the dielectric layer 504 during the same RIE process. The formed SNC holes 502 can expose the terminal (either a source or a drain) of each transistor in the transistor array. Each SNC hole 502 has an interior side surface 514 and a bottom surface 516.

At least one row of SNC holes 502 of array 500 can be modified by a first directional ion beam etching (IBE) process. FIG. 5C illustrates a top view of the array 500 modified by the first directional IBE process. FIG. 5D illustrates a side view of a cross section of the modified array 500 along cut line BB′. For example, as shown in FIGS. 5C and 5D, the SNC holes in row 506 and row 510 are modified, and the modified SNC holes are now referred to as SNC holes 502a. As shown in FIG. 5D, each SNC hole 502a in row 506 and row 510 is formed from a corresponding SNC hole 502 by creating an interior side surface 518a (e.g., a chamfer) between the interior side surface 514 and the top surface 512 of the dielectric layer 504. The interior side surface 518a can be formed by the first directional IBE process, which applies an ion beam to the dielectric layer 504 at an angle of incidence θ₁ with respect to the Z direction. The interior side surface 518a is on a first side (e.g., the right side) of a top portion 520a of the SNC hole 502a since the ion beam is directed towards the first side. In some implementations, a tangent plane of the interior side surface 518a is perpendicular to angle of incidence of the ion beam in the first directional IBE process. In some implementations, an angle between the Z direction (or the reference plane 524) and the interior side surface 518a is in a range between 20 degrees and 70 degrees.

In some implementations, to prevent the first directional IBE process from modifying the SNC holes 502 of the row 508, the row 508 can be covered by a mask (e.g., a mask 519a as shown in FIG. 5C) during the first directional IBE process.

As shown in FIG. 5C, each SNC hole 502a has an opening (also referred to as a top cross section) 521a. The opening 521a is divided by a reference plane 524 of the SNC hole 502a into a part 522a and a part 523a. In each SNC hole, the reference plane 524 can be defined as a plane that cuts through a center of the bottom surface 516 of the SNC hole and extends along the Z direction and the Y direction. Each SNC hole 502a (and 502) can have a center cross section 526 in an intersection of the reference plane 524 and the SNC hole 502a. The center cross section 526 can be perpendicular to the X direction and can extend from the center of the bottom surface 516 to the opening 521a. The opening 521a is also divided by the center cross section 526 into a part 522a and a part 523a. The opening 521a is asymmetric with respect to the reference plane 524 (and the center cross section 526). The part 522a of the opening 521a extends from the reference plane 524 (and the center cross section 526) along a first direction (e.g., the X direction). The part 523a of the opening 521a extends from the reference plane 524 (and the center cross section 526) along a second direction opposite to the first direction. Along the first direction, a size of the part 522a is greater than a size of the part 523a.

In some implementations, the row 508 of the array 500 can be modified by a second directional IBE process. FIG. 5E illustrates a top view of the array 500 modified by the second directional IBE process. FIG. 5F illustrates a side view of a cross section of the modified array 500 along cut line CC′ of FIG. 5E. As shown in FIG. 5F, each SNC hole 502b in the row 508 is formed from a corresponding SNC hole 502 by creating an interior side surface 518b (e.g., a chamfer) between the interior side surface 514 and the top surface 512 of the dielectric layer 504. The interior side surface 518b can be formed by the second directional IBE process, which applies an ion beam to the dielectric layer 504 at an angle of incidence θ₂ with respect to the Z direction. The interior side surface 518b is on a second side (e.g., the left side) of a top portion 520b of the SNC hole 502b since the ion beam in the second directional IBE process is directed towards the second side. The angle of incidence θ₂ used in the second directional IBE process can be either the same or different from the angle of incidence θ₁ used in the first directional IBE process. In some implementations, a tangent plane of the interior side surface 518b is perpendicular to angle of incidence of the ion beam in the second directional IBE process. In some implementations, an angle between the Z direction (or the reference plane 524 and the center cross section 526) and a tangent plane of the interior side surface 518b is in a range between 20 degrees and 70 degrees.

In some implementations, to prevent the second directional IBE process from modifying the SNC holes 502a of the row 506 and the row 510, each of the row 506 and the row 510 can be covered by a mask (e.g., masks 519b as shown in FIG. 5E) during the second directional IBE process.

In some implementations, the first directional IBE process and the second directional IBE process can use high-energy and noble ions (such as argon or xenon).

As shown in FIG. 5E, each SNC hole 502b has an opening (also referred to as a top cross section) 521b. The opening 521b is divided by the reference plane 524 (and the center cross section 526) of the SNC hole 502b into a part 522b and a part 523b. The opening 521b is asymmetric with respect to the reference plane 524 (and the center cross section 526). The part 522b of the opening 521b extends from the reference plane 524 (and the center cross section 526) along the first direction (e.g., the X direction). The part 523b of the opening 521a extends from the reference plane 524 (and the center cross section 526) along the second direction opposite to the first direction. Along the first direction, a size of the part 523b is greater than a size of the part 522b.

SNC structures can be formed by filling one or more conductive materials into SNC holes (e.g., SNC holes 502a in row 506 and row 510 and SNC holes 502b in row 508) of the array 500. The one or more conductive materials can include W, Co, Cu, Al, doped silicon, silicides, or any combination thereof. Due to the chamfer in each SNC hole (e.g., interior side surface 518a of FIG. 5D and interior side surface 518b of FIG. 5F), a top portion of a formed SNC structure (e.g., as shown in FIG. 4) can have an asymmetric structure and can expand or extend towards a horizontal direction (e.g., in the X-Y plane). Such a top portion can serve as a landing pad for a storage structure to be formed on top of the SNC structure. The landing pad can accommodate a lateral offset between a position of the storage structure and a position of the SNC structure (e.g., as shown in FIG. 1B), and thus can provide a reliable connection between the storage structure and the SNC structure and allow the storage structure to have a larger CD.

In some implementations, two separate directional IBE processes can be performed (as shown in FIG. 5E), so that two adjacent rows of SNC holes can be expanded towards opposite sides. For example, SNC holes in even index rows (e.g., row 506) can be expanded towards one side, and SNC holes in odd index rows (e.g., row 508) can be expanded towards an opposite side. It is understood that the SNC holes and the fabrication methods shown in FIGS. 5A-5F are for illustration purposes only, and that any suitable variations can be applied in practice depending on the patterns and structures of a transistor array and a storage structure array that are connected by the SNC structures. In some implementations, SNC holes in even index rows (e.g., row 506 and row 510) are expanded towards one side, and SNC holes in odd index rows (e.g., row 508) are not expanded. In other words, the second directional IBE process can be skipped, and covering masks (e.g., mask 519a) are applied to the SNC holes in odd index rows in the first directional IBE process. In some other implementations, only one directional IBE process (e.g., the first directional IBE process) is performed, and the SNC holes (in even index rows and odd index rows) are expanded toward the same side. That is, the second directional IBE process can be skipped, and no covering masks are used in the first directional IBE process.

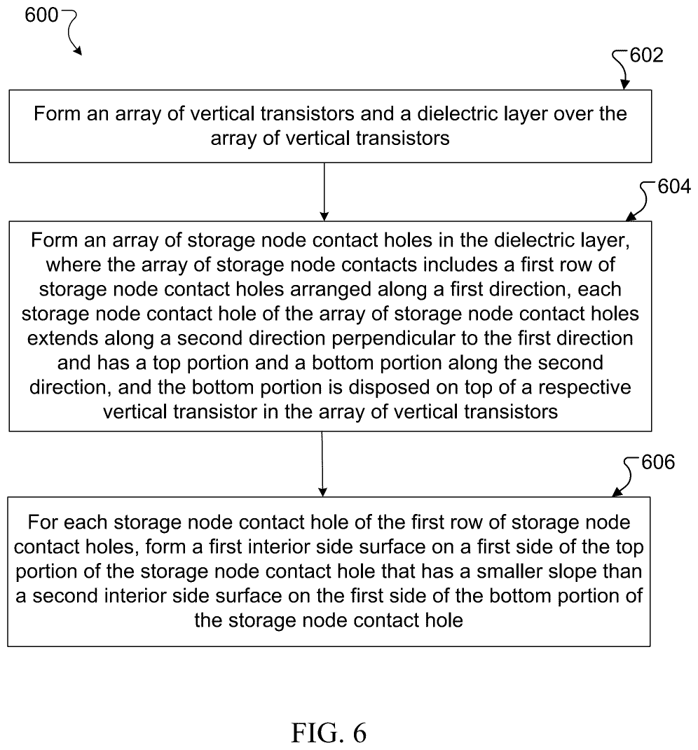

FIG. 6 illustrates a flow chart of an example process 600. The process 600 can be performed, for example, to from SNC structures in a semiconductor device (e.g., a DRAM). The semiconductor device can be, e.g., the semiconductor device 200 of FIG. 2 or the semiconductor device 300 of FIGS. 3A-3B. The SNC structures can be similar to, or same as, the SNC structure 142 of FIG. 2, the SNC structure 318 of FIG. 3B, or the SNC structure 400 of FIG. 4. The process 600 can be described in view of FIGS. 5A-5F. The process 600 can include the fabrication process of forming the semiconductor structures in FIGS. 5A-5F. It is understood that the operations shown in process 600 are not exhaustive and that other operations can be performed as well before, after, or between any of the illustrated operations. Further, some of the operations may be performed simultaneously, or in a different order than shown in FIG. 6.

At operation 602, an array of vertical transistors (e.g., the vertical transistor 126 of FIG. 2) and a dielectric layer (e.g., the dielectric layer 504 of FIGS. 5A-5F) over the array of vertical transistors are formed.

At operation 604, an array of SNC holes is formed in the dielectric layer. The array of SNC holes includes a first row (row 506 of FIG. 5E) of SNC holes arranged along a first direction (e.g., the X direction). Each SNC hole of the array of SNC holes extends along a second direction (e.g., the Z direction) perpendicular to the first direction and has a top portion and a bottom portion along the second direction. The bottom portion being disposed on top of a respective vertical transistor in the array of vertical transistors.

In some implementations, the array of storage node contact holes is formed by a same RIE process using a zero angle of incidence with respect to the second direction.

At operation 606, for each storage node contact hole of the first row of storage node contact holes, a first interior side surface (e.g., the interior side surface 518a of FIG. 5D) on a first side (e.g., the right side) of the top portion of the storage node contact hole is formed. A tangent plane of the first interior side surface has a smaller slope than a tangent plane of a second interior side surface (e.g., the interior side surface 514) on the first side of the bottom portion of the storage node contact hole with respect to the X direction.

In some implementations, the first interior side surface of each of the first row of storage node contact holes is formed by a first directional IBE process using a first angle of incidence (e.g., θ₁ as shown in FIG. 5D) perpendicular to the first interior side surface.

In some implementations, the array of storage node contacts further includes a second row of storage node contact holes adjacent to the first row of storage node contact holes. The process 600 further includes, for each storage node contact hole of the second row of storage node contact holes, forming a third interior side surface on the first side of a top portion of the storage node contact hole. A tangent plane of the third interior side surface has a smaller slope than a tangent plane of a fourth interior side surface on the first side of a bottom portion of the storage node contact hole with respect to the X direction. The tangent plane of the third interior side surface and the tangent plane of the first interior side surface have a same slope with respect to the X direction. The third interior side surface of each of the second row of storage node contact holes is formed during the first directional IBE process.

In some other implementations, the array of storage node contacts further includes a second row (e.g., row 508 of FIG. 5E) of storage node contact holes adjacent to the first row of storage node contact holes. The process 600 further includes, for each storage node contact hole of the second row of storage node contact holes, forming a third interior side surface (e.g., the interior side surface 518b of FIG. 5F) on a second side (e.g., the left side) of a top portion of the storage node contact hole. The tangent plane of the third interior side surface has a smaller slope than a tangent plane of a fourth interior side surface (e.g., the interior side surface 514) on the second side of a bottom portion of the storage node contact hole with respect to the X direction. The second side is opposite to the first side. In some implementations, the third interior side surface of each of the second row of storage node contact holes is formed during a second directional IBE process using a second angle of incidence (e.g., θ₂ as shown in FIG. 5F) perpendicular to the third interior side surface. In some implementations, openings of the second row of storage node contact holes are covered during the first directional IBE process (e.g., by mask 519a of FIG. 5C), and openings of the first row of storage node contact holes are covered during the second directional IBE process (e.g., by mask 519b of FIG. 5E).

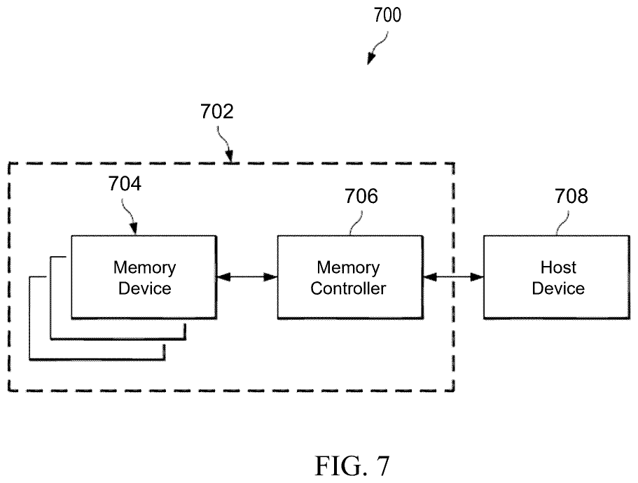

FIG. 7 illustrates a block diagram of an example system 700. The system 700 can have one or more semiconductor devices (e.g., memory devices), according to one or more implementations of the present disclosure. The system 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 7, the system 700 can include a host device 708 and a memory system 702 having one or more memory devices 704 and a memory controller 706. Host device 708 can include a processor of an electronic device, such as a central processing unit (CPU), or a system-on-chip (SoC), such as an application processor (AP). Host device 708 can be configured to send or receive data to or from the one or more memory devices 704.

A memory device 704 can be any memory device disclosed herein, such as a memory device (e.g., a DRAM device) as shown in FIGS. 2 and 3A-3B or a memory device that includes SNC structures as shown in FIG. 4. In some implementations, a memory device 704 includes a NAND Flash memory. Memory controller 706 (a.k.a., a controller circuit) is coupled to memory device 704 and host device 708. Consistent with implementations of the present disclosure, memory device 704 can include a plurality of conductive interconnections through a cover layer that are in contact with conductive pads in a conductive pad layer, and memory controller 706 can be coupled to memory device 704 through at least one of the plurality of conductive interconnections. Memory controller 706 is configured to control memory device 704. For example, memory controller 706 may be configured to operate a plurality of channel structures via word lines. Memory controller 706 can manage data stored in memory device 704 and communicate with host device 708.

In some implementations, memory controller 706 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 706 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 706 can be configured to control operations of memory device 704, such as read, erase, and program (or write) operations. Memory controller 706 can also be configured to manage various functions with respect to the data stored or to be stored in memory device 704 including, but not limited to bad-block management, garbage collection, logical-to-physical address conversion, wear leveling, etc. In some implementations, memory controller 706 is further configured to process error correction codes (ECCs) with respect to the data read from or written to memory device 704. Any other suitable functions may be performed by memory controller 706 as well, for example, formatting memory device 704.

Memory controller 706 can communicate with an external device (e.g., host device 708) according to a particular communication protocol. For example, memory controller 706 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 706 and one or more memory devices 704 can be integrated into various types of storage devices, for example, be included in the same package, such as a universal Flash storage (UFS) package or an eMMC package. That is, memory system 702 can be implemented and packaged into different types of end electronic products. In one example as shown in FIG. 7, memory controller 706 and a single memory device 704 may be integrated into a memory card 702. Memory card 702 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g.,.+−. 10%,.+−20%, or.+−. 30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
an array of memory cells comprising a first row of memory cells arranged along a first direction, wherein:
at least one memory cell of the first row of memory cells comprises a first vertical transistor, a first storage node contact structure, and a first storage structure that are stacked along a second direction perpendicular to the first direction;
the first storage node contact structure comprises a first top portion in contact with the first storage structure and a first bottom portion in contact with the first vertical transistor; and
a first top cross section of the first top portion is asymmetric.

2. The semiconductor device according to claim 1, wherein
the first top cross section of the first top portion is asymmetric with respect to a first center cross section of the first storage node contact structure;
the first center cross section is perpendicular to the first direction and extends from a center of a first bottom cross section of the first bottom portion to the first top cross section;
the first top cross section comprises a first part extending from the first center cross section along the first direction and a second part extending from the first center cross section along a fourth direction opposite to the first direction; and
along the first direction, a size of the first part of the first top cross section is greater than a size of the second part of the first top cross section.

3. The semiconductor device according to claim 2, wherein:
the array of memory cells further comprises a second row of memory cells adjacent to the first row of memory cells;
at least one memory cell of the second row of memory cells comprises a second vertical transistor, a second storage node contact structure, and a second storage structure that are stacked along the second direction;
the second storage node contact structure comprises a second top portion in contact with the second storage structure and a second bottom portion in contact with the second vertical transistor;
a second top cross section of the second top portion is asymmetric with respect to a second center cross section of the second storage node contact structure;
the second center cross section is perpendicular to the first direction and extends from a center of a second bottom cross section of the second bottom portion to the second top cross section;
the second top cross section comprises a first part extending from the second center cross section along the first direction and a second part extending from the second center cross section along the fourth direction; and
along the first direction, a size of the second part of the second top cross section is greater than a size of the first part of the second top cross section.

4. The semiconductor device according to claim 1, wherein the first vertical transistor is coupled to the first storage structure through the first storage node contact structure.

5. The semiconductor device according to claim 1, wherein the first storage node contact structure comprises at least one of a metal, a silicide, or a doped silicon.

6. The semiconductor device according to claim 1, wherein the first vertical transistor comprises one of a single-gate structure, a two-gates structure, a three-gates structure, or a gate all around (GAA) structure.

7. The semiconductor device according to claim 1, wherein:
the array of memory cells is coupled to a peripheral circuit through conductive bonding contacts comprised in a bonding layer; and
the bonding layer further comprises a dielectric material electrically isolating the conductive bonding contacts.

8. A semiconductor device, comprising:
an array of memory cells comprising a first row of memory cells arranged along a first direction, wherein:
at least one memory cell of the first row of memory cells comprises a first vertical transistor, a first storage node contact structure, and a first storage structure that are stacked along a second direction perpendicular to the first direction;
the first storage node contact structure comprises a top portion in contact with the first storage structure and a bottom portion in contact with the first vertical transistor; and
a tangent plane of a side surface of the top portion of the first storage node contact structure on a first side has a smaller slope than a tangent plane of a side surface of the bottom portion on the first side with respect to the first direction.

9. The semiconductor device according to claim 8, wherein:
the tangent plane of the side surface of the top portion of the first storage node contact structure on the first side has a smaller slope than a tangent plane of a side surface of the top portion on a second side with respect to the first direction; and
the first side and the second side are opposite to each other with respect to a third direction perpendicular to the first direction and the second direction.

10. The semiconductor device according to claim 8, wherein a dimension of a cross section of the top portion of the first storage node contact structure is greater than a dimension of a cross section of the bottom portion of the first storage node contact structure.

11. The semiconductor device according to claim 8, wherein an angle between the side surface of the top portion of the first storage node contact structure on the first side and the first direction varies from 20 degrees to 70 degrees.

12. The semiconductor device according to claim 9, wherein:
the array of memory cells further comprises a second row of memory cells adjacent to the first row of memory cells;
at least one memory cell of the second row of memory cells comprises a second vertical transistor, a second storage node contact structure, and a second storage structure that are stacked along the second direction;
the second storage node contact structure comprises a top portion in contact with the second storage structure and a bottom portion in contact with the second vertical transistor; and
a tangent plane of a side surface of the top portion of the second storage node contact structure on the second side has a smaller slope than a tangent plane of a side surface of the bottom portion of the second storage node contact structure on the second side with respect to the first direction.

13. The semiconductor device according to claim 8, wherein the first vertical transistor is coupled to the first storage structure through the first storage node contact structure.

14. The semiconductor device according to claim 8, wherein the first storage node contact structure comprises at least one of a metal, a silicide, or a doped silicon.

15. A method, comprising:
forming an array of vertical transistors and a dielectric layer over the array of vertical transistors;
forming an array of storage node contact holes in the dielectric layer, wherein the array of storage node contact holes comprises a first row of storage node contact holes arranged along a first direction, each storage node contact hole of the array of storage node contact holes extends along a second direction perpendicular to the first direction and has a top portion and a bottom portion along the second direction, and the bottom portion is disposed on top of a respective vertical transistor in the array of vertical transistors; and
for each storage node contact hole of the first row of storage node contact holes, forming a first interior side surface on a first side of the top portion of the storage node contact hole, wherein a tangent plane of the first interior side surface has a smaller slope than a tangent plane of a second interior side surface on the first side of the bottom portion of the storage node contact hole with respect to the first direction.

16. The method according to claim 15, wherein forming the array of storage node contact holes comprises:
forming the array of storage node contact holes by a same reactive ion etching (RIE) process using a zero angle of incidence with respect to the second direction.

17. The method according to claim 15, wherein forming the first interior side surface of each of the first row of storage node contact holes comprises:
forming the first interior side surface of each of the first row of storage node contact holes by a first directional ion beam etching (IBE) process using a first angle of incidence perpendicular to the first interior side surface.

18. The method according to claim 17, wherein the array of storage node contact holes further comprises a second row of storage node contact holes adjacent to the first row of storage node contact holes, and wherein the method further comprising:
for each storage node contact hole of the second row of storage node contact holes, forming a third interior side surface on the first side of a top portion of the storage node contact hole, wherein a tangent plane of the third interior side surface has a smaller slope than a tangent plane of a fourth interior side surface on the first side of a bottom portion of the storage node contact hole with respect to the first direction, wherein:
the tangent plane of the third interior side surface and the tangent plane of the first interior side surface have a same slope with respect to the first direction; and
the third interior side surface of each of the second row of storage node contact holes is formed during the first directional IBE process.

19. The method according to claim 17, wherein the array of storage node contact holes further comprises a second row of storage node contact holes adjacent to the first row of storage node contact holes, and wherein the method further comprising:
for each storage node contact hole of the second row of storage node contact holes, forming a third interior side surface on a second side of a top portion of the storage node contact hole, wherein a tangent plane of the third interior side surface has a smaller slope than a tangent plane of a fourth interior side surface on the second side of a bottom portion of the storage node contact hole with respect to the first direction, wherein the second side is opposite to the first side.

20. The method according to claim 19, wherein:
the third interior side surface of each of the second row of storage node contact holes is formed during a second directional IBE process using a second angle of incidence perpendicular to the third interior side surface;
openings of the second row of storage node contact holes are covered during the first directional IBE process; and
openings of the first row of storage node contact holes are covered during the second directional IBE process.
